(19) United States
(12) Patent Application Publication
(10) Pub. No.: US 2026/0324110 A1
(43) Pub. Date: Oct. 15, 2026

(54) IMAGE SENSOR

(71) Applicant: SAMSUNG ELECTRONICS CO., LTD., Suwon-si (KR)

(72) Inventors: Yunhyeok KIM, Suwon-si (KR); Seungki JUNG, Suwon-si (KR); Seungki BAEK, Suwon-si (KR); Masato FUJITA, Suwon-si (KR)

(73) Assignee: SAMSUNG ELECTRONICS CO., LTD., Suwon-si (KR)

(21) Appl. No.: 19/533,524

(22) Filed: Feb. 9, 2026

(30) Foreign Application Priority Data
Apr. 14, 2025 (KR) 10-2025-0048396

(51) Int. Cl. H10F 39/00; H10F 39/18

(52) U.S. Cl. CPC H10F 39/80373; H10F 39/014; H10F 39/182; H10F 39/807

(57) ABSTRACT

Provided is an image sensor. The image sensor may include a substrate having pixel regions defined by a pixel separator, floating diffusion regions arranged in the pixel regions of the substrate, a plurality of photoelectric transformation regions arranged adjacent to the floating diffusion regions in the substrate, and a plurality of transmission gates respectively arranged adjacent to the plurality of photoelectric transformation regions, the plurality of transmission gates respectively extending in different directions toward the floating diffusion regions, a plurality of device separators respectively arranged around the plurality of transmission gates and defining active regions having an asymmetry structure with reference to a first direction and a second direction orthogonal to the first direction, and a gate electrode crossing the active region in the first direction and having a first gate sidewall and a second gate sidewall spaced apart from each other in the second direction.

### CROSS-REFERENCE TO RELATED APPLICATION

This application is based on and claims priority under 35 U.S.C. § 119 to Korean Patent Application No. 10-2025-0048396, filed on Apr. 14, 2025, in the Korean Intellectual Property Office, the disclosure of which is incorporated by reference herein in its entirety.

### BACKGROUND

The inventive concept relates to an image sensor, and more particularly, to an image sensor including a photodiode.

Image sensors are apparatuses configured to convert optical image signals to electric signals. An image sensor includes a plurality of pixels, each of which receives incident light and converts the incident light into an electric signal and includes a photodiode region and a pixel circuit, wherein the pixel circuit outputs a pixel signal by using electric charge generated in the photodiode region. In accordance with the increase in the integrity of the image sensor, a size of each pixel decreases and sizes of components in the pixel circuit also decreases, and accordingly, leakage current and the like may occur through the pixel circuit and cause degradation in the quality of the image sensor.

### SUMMARY

The inventive concept provides an image sensor having improved reliability.

In addition, technical goals to be achieved by the inventive concept is not limited to the goals mentioned above, and other goals may be clearly understood to those skilled in the art from the following descriptions.

According to an aspect of the inventive concept, there is provided an image sensor including a substrate having a pixel region defined by a pixel separator, a floating diffusion region arranged in the pixel region of the substrate, a plurality of photoelectric transformation regions arranged around the floating diffusion region in the substrate, a plurality of transmission gates respectively arranged adjacent to the plurality of photoelectric transformation regions, wherein the plurality of transmission gates may extend toward the floating diffusion region respectively in different directions, and a semiconductor device including a plurality of device separators and a gate electrode, the plurality of device separators being respectively arranged adjacent to the plurality of transmission gates and defining an active region having an asymmetrical structure with reference to a first direction and a second direction orthogonal to the first direction, and the gate electrode crossing the active region in the first direction and having a first gate sidewall and a second gate sidewall spaced apart from each other in the second direction, wherein the pixel separator may include lateral extending portions extending in the first direction and the second direction toward a center portion of the pixel region, and in a plan view, the plurality of photoelectric transformation regions arranged in the pixel region may be distinguished from each other by being arranged at two sides of lateral extending portions in the first direction, and the floating diffusion region may be arranged in a space between the lateral extending portions arranged in the pixel region and facing each other in the second direction.

According to another aspect of the inventive concept, there is provided an image sensor including a substrate having a pixel region defined by a pixel separator, a floating diffusion region arranged in the pixel region of the substrate, a plurality of photoelectric transformation regions arranged around the floating diffusion region in the substrate, a plurality of transmission gates respectively arranged adjacent to the plurality of photoelectric transformation regions, and a semiconductor device comprising a plurality of device separators and a gate electrode, the plurality of device separators being respectively arranged adjacent to the plurality of transmission gates and defining an active region having an asymmetrical structure with reference to a first direction, and the gate electrode crossing the active region in the first direction and having a first gate sidewall and a second gate sidewall spaced apart from each other in a second direction orthogonal to the first direction, wherein the pixel separator may include lateral extending portions extending in the first direction and the second direction toward a center portion of the pixel region, and in a plan view, the plurality of transmission gates may be respectively connected to word lines, the plurality of photoelectric transformation regions arranged in the pixel region may be distinguished from each other by being arranged at two sides of the lateral extending portions in the first direction, and the floating diffusion region may be arranged in a space between the lateral extending portions arranged in the pixel region and facing each other in the second direction.

According to another aspect of the inventive concept, there is provided an image sensor including a substrate having a pixel region defined by a pixel separator, a floating diffusion region arranged in the pixel region of the substrate, a plurality of photoelectric transformation regions arranged around the floating diffusion region in the substrate, a plurality of transmission gates respectively arranged adjacent to the plurality of photoelectric transformation regions, wherein the plurality of transmission gates may extend toward the floating diffusion region respectively in different directions, a semiconductor device comprising a plurality of device separators and a gate electrode, the plurality of device separators being respectively arranged adjacent to the plurality of transmission gates and defining an active region having an asymmetry structure with reference to a first direction and a second direction orthogonal to the first direction and the gate electrode crossing the active region in the first direction and having a first gate sidewall and a second gate sidewall spaced apart from each other in the second direction, a first impurity region arranged in the active region and adjacent to the first gate sidewall; and a second impurity region adjacent to the second gate sidewall, wherein the pixel separator may include lateral extending portions extending in the first direction and the second direction toward a center portion of the pixel region, wherein the active region constructs first through fourth active regions and includes an active center portion overlapping the gate electrode, a first active protrusion in which the first impurity region is arranged, and a second active protrusion in which the second impurity region is arranged, wherein the first active protrusion and the second active protrusion may be arranged in a point symmetry with reference to a center of the active center portion, and in a plan view, the plurality of photoelectric transformation regions arranged in the pixel region may be distinguished from each other by being arranged at two sides of the lateral extending portions in the first direction, the floating diffusion region may be arranged in a space between the lateral extending portions arranged in the pixel region and facing each other in the second direction, at least one of the first through fourth active regions may form a shape different from others, and the gate electrodes arranged adjacent to the first fourth active regions may have a same shape.

In some embodiments, a method of manufacturing an image sensor may include forming photoelectric transformation regions on a substrate through ion injection, forming a pixel separator extending from a first surface of the substrate into the substrate, forming a device separator for a region of the first surface of the substrate, forming a gate electrode near the first surface of the substrate, forming a spacer on a sidewall of the gate electrode, forming a source drain region and a floating diffusion region near the first surface of the substrate, forming a buried insulating layer covering the gate electrode, forming a contact penetrating the buried insulating layer to be electrically connected to the gate electrode, and forming a back-surface insulating layer, a passivation layer, a color filter, and a microlens on a second surface of the substrate opposite to the first surface of the substrate, wherein the gate electrode may correspond to a gate electrode of at least one of a reset transistor, a source follower transistor, and a selection transistor, and the pixel separator may include a lateral extending portion.

In some embodiments (or in the method of manufacturing an image sensor, according to some embodiments), the pixel separator may extend from the first surface to the second surface, and a length of the lateral extending portion in a vertical direction may be less than a length of the pixel separator in the vertical direction.

In some embodiments, in a plan view, the pixel region may be defined by the pixel separator, and the plurality of photoelectric transformation regions arranged in the pixel region may be distinguished from each other by being arranged at two sides of the lateral extending portion.

In some embodiments, the pixel separator may define an active region, the active region may construct first through fourth active regions, and in a plan view, at least one of the first through fourth active regions may form a different shape, and the gate electrodes arranged near the first through fourth active regions may have a same shape.

In some embodiments, the active region may have an asymmetrical structure with reference to a first direction and a second direction orthogonal to the first direction, the gate electrode may cross the active region in the first direction and have a first gate sidewall and a second gate sidewall that are spaced apart from each other in the second direction.

In some embodiments, a first impurity region may be arranged adjacent to the first gate sidewall, a second impurity region may be arranged adjacent to the second gate sidewall, wherein the active region may include an active center portion overlapping the gate electrode, a first active protrusion in which the first impurity region is arranged, and a second active protrusion in which the second impurity region is arranged, and the first active protrusion and the second active protrusion may be arranged in a point symmetry with reference to a center of the active center portion, the active center portion may have a first width in the first direction, the first impurity region may have a second width in the first direction, the second impurity region may have a third width in the first direction, and the first width may be greater than the second width and the third width.

In some embodiments, the device separator may include a first separation sidewall and a second separation sidewall which are in contact with the active center portion and parallel to the second direction, and a third separation sidewall and a fourth separation sidewall which are in contact with the active center portion and parallel to the first direction, and when assuming that a straight line connecting a first point, at which the first active protrusion meets the active center portion and which is most adjacent to the fourth separation sidewall, and a second point, at which the second active protrusion meets the active center portion and which is most adjacent to the second separation sidewall, is a first straight line, and a straight line connecting a third point, at which the first active protrusion meets the active center portion and which is most adjacent to the third separation sidewall, and a fourth point, at which the second active protrusion meets the active center portion and which is most adjacent to the third separation sidewall, is a second straight line, an angle formed by the first straight line and the fourth separation sidewall and an angle formed by the second straight line and the third separation sidewall may be each an acute angle.

In some embodiments, the first impurity region may be arranged adjacent to the first gate sidewall, the second impurity region may be arranged adjacent to the second gate sidewall, wherein the active region may include an active center portion overlapping the gate electrode, a first active protrusion in which the first impurity region is arranged, and a second active protrusion in which the second impurity region is arranged, and a first width of the first active center portion, a second width of the first impurity region, and a third width of the second impurity region, which extend in the first direction, may have a same size.

In some embodiments, a third straight line connecting a center of the first active protrusion and a center of the second active protrusion may be not parallel to either the first direction or the second direction, and the device separator may include a fifth separation sidewall and a sixth separation sidewall which are in contact with the active center portion and parallel to the third straight line, and an angle formed by the third straight line and an axis in the first direction may be an acute angle.

In some embodiments, the first impurity region may be arranged adjacent to the first gate sidewall, the second impurity region may be arranged adjacent to the second gate sidewall, wherein the active region may include an active center portion overlapping the gate electrode, a first active protrusion in which the first impurity region is arranged, and a second active protrusion in which the second impurity region is arranged, and the first active protrusion and the second active protrusion may be arranged in a symmetry to each other with reference to an axis in a second direction passing a center of the active center portion, and an angle formed by a fourth straight line, which connects a center of the first active protrusion and a center of the active center portion, and a fifth straight line, which connects a center of the second active protrusion and the center of the active center portion, may include an obtuse angle.

### BRIEF DESCRIPTION OF THE DRAWINGS

Embodiments will be more clearly understood from the following detailed description taken in conjunction with the accompanying drawings in which:

FIG. 1 is a top-plan view of an active region in a semiconductor device included in an image sensor according to an embodiment;

FIG. 2 is a top-plan view of a semiconductor device included in an image sensor according to an embodiment;

FIG. 3 is a cross-sectional view taken along line A-A′ shown in FIG. 2;

FIG. 4 is a cross-sectional view taken along line B-B′ shown in FIG. 2;

FIG. 5 is a cross-sectional view taken along line C-C′ shown in FIG. 2;

FIG. 6 is a top-plan view of a semiconductor device included in an image sensor according to another embodiment;

FIG. 7 is a top-plan view of a semiconductor device included in an image sensor according to another embodiment;

FIG. 8 is a top-plan view of a semiconductor device included in an image sensor according to another embodiment;

FIG. 9 is a layout diagram illustrating an image sensor according to an embodiment;

FIG. 10 is a top-plan view of an image sensor according to an embodiment;

FIG. 11 is a cross-sectional view taken along line A1-A1′ shown in FIG. 10;

FIG. 12 is a top-plan view of an image sensor according to another embodiment;

FIGS. 13 to 20 are cross-sectional views illustrating a method of manufacturing an image sensor, according to an embodiment;

FIG. 21 is an equivalent circuit diagram of a pixel in an image sensor according to an embodiment; and

FIG. 22 is a block diagram illustrating a configuration of an image sensor according to an embodiment.

### DETAILED DESCRIPTION OF THE EMBODIMENTS

As embodiments may be variously modified and have various forms, some embodiments will be illustrated in the drawings and described in detail. However, this is not to limit the embodiments to a specific form of disclosure. In addition, embodiments described hereinafter are merely examples, and various modifications may be made therefrom.

Use of any examples or indicative terms are only used to provide detailed descriptions of the inventive concept, and unless defined by the claims, the scope of the inventive concept is not limited to the examples or indicative terms.

Hereinafter, unless particularly described, in the present specification, a vertical direction may be defined as Z direction, and a first horizontal direction and a second horizontal direction may each be defined as a horizontal direction perpendicular to the Z direction. The first horizontal direction may be referred to as X direction, and the second horizontal direction may be referred to as Y direction. A vertical level may refer to as a height level in the vertical direction (the Z direction). A horizontal width in the first horizontal direction may refer to a length in the horizontal direction (the X direction and/or the Y direction), and a vertical length may refer to a length in the vertical direction (the Z direction).

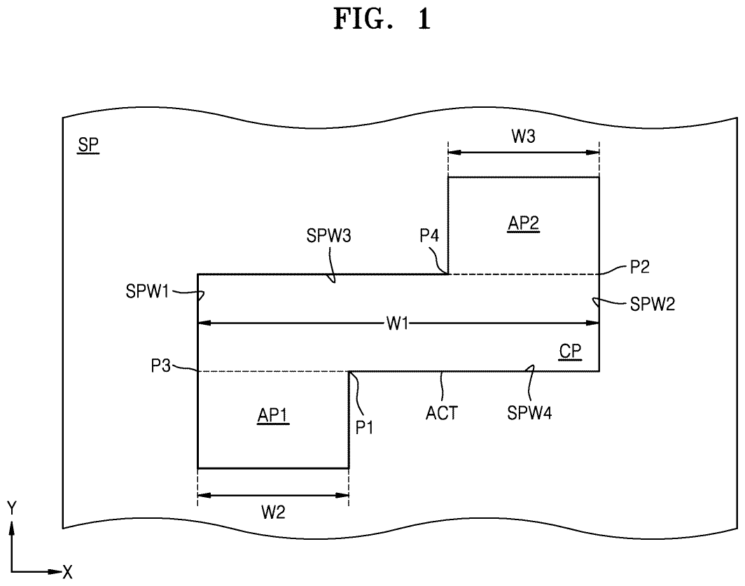

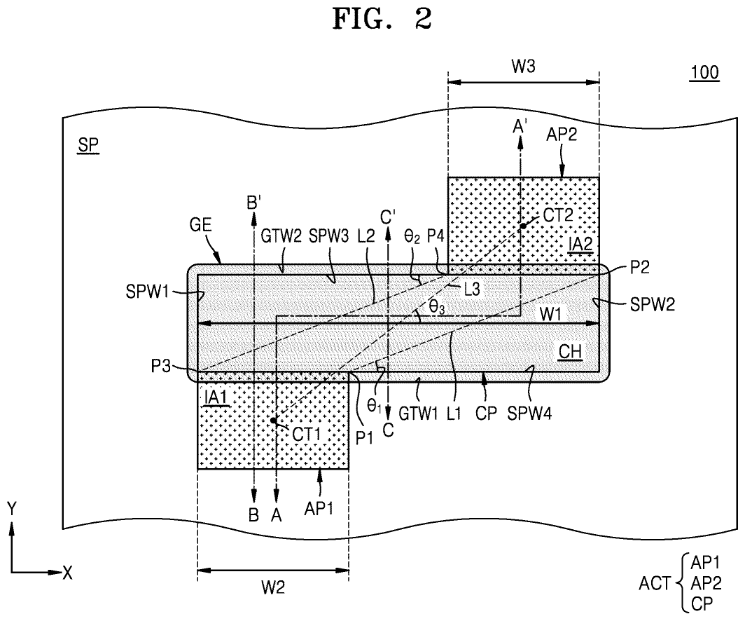

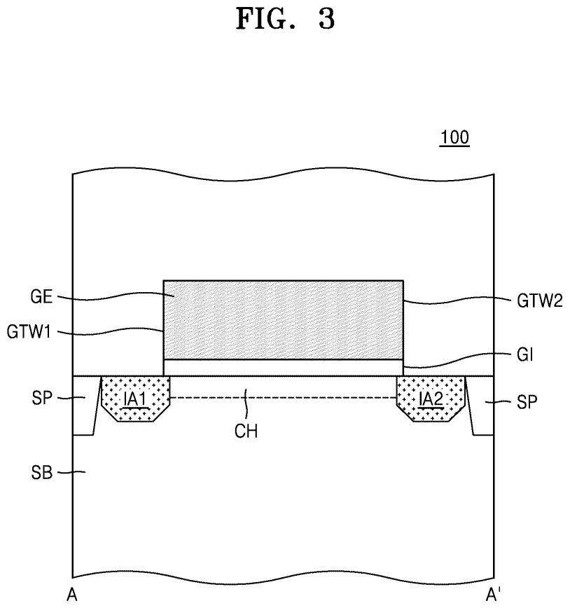

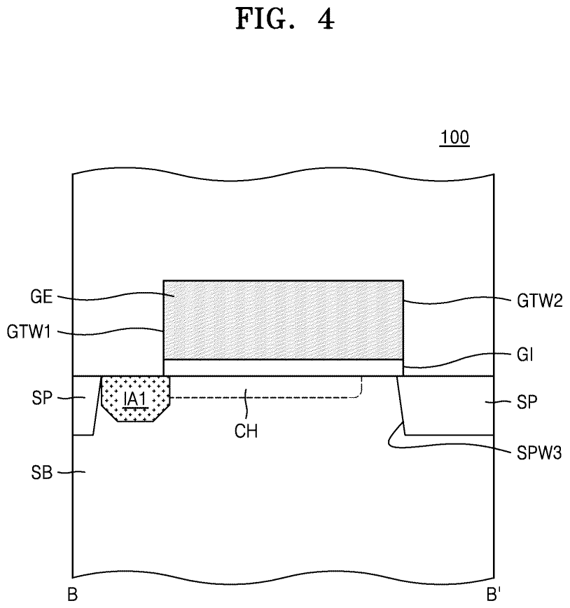

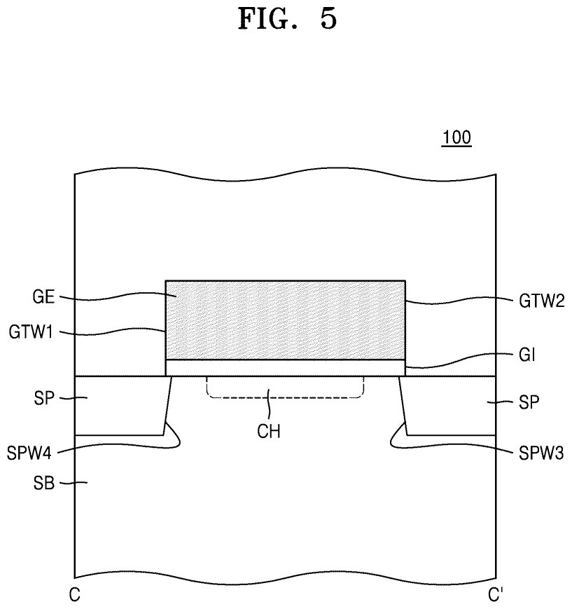

FIG. 1 is a top-plan view of an active region in a semiconductor device included in an image sensor according to an embodiment. FIG. 2 is a top-plan view of the semiconductor device included in the image sensor according to an embodiment. FIG. 3 is a cross-sectional view taken along line A-A′ shown in FIG. 2. FIG. 4 is a cross-sectional view taken along line B-B′ shown in FIG. 2. FIG. 5 is a cross-sectional view taken along line C-C′ shown in FIG. 2.

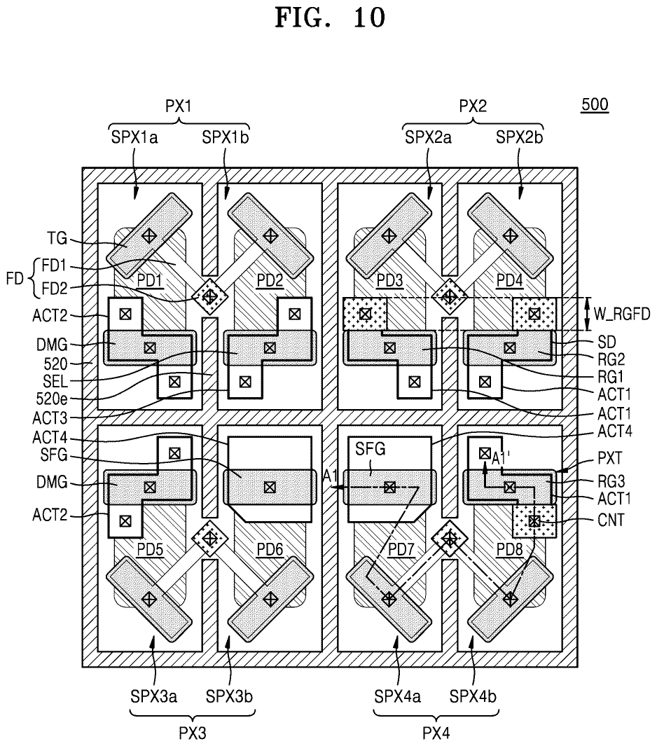

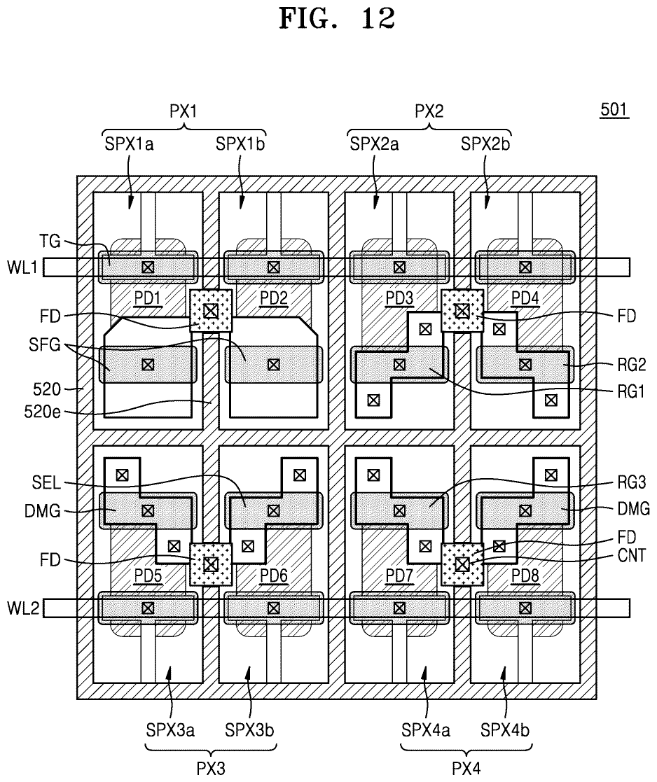

Referring to FIGS. 1 to 5, a semiconductor device 100 according to an embodiment may be a configuration included in an image sensor 500 illustrated in FIG. 10 and an image sensor 501 illustrated in FIG. 12. In the semiconductor device 100 according to an embodiment, a device separator SP may be arranged in a substrate SB to define an active region ACT. The semiconductor device 100 may correspond to a portion of a peripheral circuit region, a core region, or a logic region of a memory device. In an embodiment, the semiconductor device 100 may include a transistor arranged in the aforementioned positions, particularly, may correspond to a portion of the image sensor 500 (see FIG. 10), and more particularly, may include at least one of a reset transistor, a source follower transistor, and a selection transistor located in the position.

The substrate SB may include a semiconductor substrate including a semiconductor material such as silicon, and for example, may include a silicon monocrystalline substrate, a silicon epitaxial layer, or a Silicon on Insulator (SOI) substrate. In addition, the substrate SB may be doped with an impurity of a first conductive type. The device separator SP may include at least one of a device isolation film and a device isolation region. The device isolation film may be formed through, for example, Shallow Trench Isolation (STI) process, and may include at least one of a silicon oxide film, a silicon nitride film, and a silicon oxynitride film. The device isolation region may include a region doped with the impurity of the first conductive type, and a concentration of the impurity with which the device isolation region is doped may be higher than a concentration of the impurity with which the substrate SB is doped.

Referring to FIG. 1, the active region ACT has a laterally asymmetrical structure with reference to the first direction X, and more particularly, may also have an asymmetrical structure with reference to the first direction X and the second direction Y orthogonal to the first direction X.

The active region ACT may be differently configured from a rectangular shape that is a shape of an active region in a general transistor. The active region ACT may include an active center portion CP, a first active protrusion AP1 arranged at one side of the active center portion CP, and a second active protrusion AP2 arranged at the other side of the active center portion CP. The device separator SP may include a first separation sidewall SPW1 and a second separation sidewall SPW2, which are in contact with the active center portion CP and parallel to the second direction Y, and a third separation sidewall SPW3 and a fourth separation sidewall SPW4 in contact with the active center portion CP and parallel to the first direction X.

The active center portion CP may have a first width W1 in the first direction X, the first active protrusion AP1 may have a second width W2 in the first direction X, and the second active protrusion AP2 may have a third width W3 in the first direction X. In an embodiment, the first separation sidewall SPW1 may extend toward the first active protrusion AP1 but not toward the second active protrusion AP2, and on the contrary, the second separation sidewall SPW2 may extend toward the second active protrusion AP2 but not toward the first active protrusion AP1. The first active protrusion AP1 and the second active protrusion AP2 may have substantially the same shape and substantially the same size, and therefore, the second width W2 may be substantially equal to the third width W3. In addition, the second width W2 and the third width W3 may be smaller than the first width W1. The first active protrusion AP1 and the second active protrusion AP2 may be arranged in a point symmetry with reference to a center of the active center portion CP. As used herein, the expression “substantially the same” or “substantially equal” may refer to having the same or equal value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

Points (i.e., a first point P1, a second point P2, a third point P3, and a fourth point P4) will be described with reference to FIGS. 1 and 2.

The active region ACT may include the first point P1 at which the first active protrusion AP1 meets the active center portion CP and which is most adjacent to the fourth separation sidewall SPW4, the second point P2 at which the second active protrusion AP2 meets the active center portion CP and which is most adjacent to the second separation sidewall SPW2, the third point P3 at which the first active protrusion AP1 meets the active center portion CP and which is most adjacent to the first separation sidewall SPW1, and the fourth point P4 at which the second active protrusion AP2 meets the active center portion CP and which is most adjacent to the third separation sidewall SPW3.

In an embodiment, the first point P1 may be spaced apart from the second separation sidewall SPW2 while the second point P2 may be located on the second separation sidewall SPW2, and the third point P3 may be located on the first separation sidewall SPW1 while the fourth point P4 may be spaced apart from the first separation sidewall SPW1.

A gate electrode GE may be arranged on the substrate SB, and may include at least one of polysilicon doped with impurities, a metal film, or a metal nitride film. The gate electrode GE may be covered by an interlayer insulating film, which may include at least one of a silicon oxide film, a silicon nitride film, a silicon oxynitride film, or a porous insulating film.

A gate insulating film GI may be arranged between the gate electrode GE and the substrate SB. The gate insulating film GI may include any one of a silicon oxide film, a silicon oxynitride film, a silicon nitride film, or a metal oxide film. The metal oxide film may include, for example, at least one of an aluminum oxide film, a hafnium oxide film, a zirconium oxide film, or a ruthenium oxide film. The gate electrode GE may have a first gate sidewall GTW1 and the second gate sidewall GTW2 facing each other.

The gate electrode GE may cross the active region ACT in the first direction X. The gate electrode GE may overlap the active center portion CP. The first active protrusion AP1 may be exposed outside the first gate sidewall GTW1. The second active protrusion AP2 may be exposed outside the second gate sidewall GTW2. A first impurity region IA1 may be arranged in the first active protrusion AP1. A second impurity region IA2 may be arranged in the second active protrusion AP2. The first impurity region IA1 and the second impurity region IA2 may be doped with an impurity of a second conductive type opposite to the first conductive type.

In FIG. 2, a first straight line L1 connecting the first point P1 and the second point P2 may be at least partially spaced apart from the second separation sidewall SPW2 and the fourth separation sidewall SPW4. In addition, a second straight line L2 connecting the third point P3 and the fourth point P4 may be at least partially spaced apart from the first separation sidewall SPW1 and the third separation sidewall SPW3. The first straight line L1 may form a first angle θ₁ together with the fourth separation sidewall SPW4. The second straight line L2 may form a second angle θ₂ together with the third separation sidewall SPW3. In an embodiment, the first angle θ₁ and the second angle θ₂ may each be an acute angle smaller than 90° and greater than 0°.

A portion of the first active protrusion AP1 may extend below the gate electrode GE, and each of the first point P1, the second point P2, the third point P3, and the fourth point P4 may overlap the gate electrode GE. In addition, the first impurity region IA1 and the second impurity region IA2 may also partially extend below the gate electrode GE.

According to an embodiment, in a plan view, the first point P1 may be interpreted as a corner point at which the first impurity region IA1 meets the first gate sidewall GTW1 and which is most adjacent to the fourth separation sidewall SPW4. Similarly, in a plan view, the second point P2 may be interpreted as a corner point at which the second impurity region IA2 meets the second gate sidewall GTW2 and which is most adjacent to the second separation sidewall SPW2. The third point P3 may be interpreted, in a plan view, as a corner point at which the first impurity region IA1 meets the first gate sidewall GTW1 and which is most adjacent to the first separation sidewall SPW1, and the fourth point P4 may be interpreted as a corner point at which the second impurity region IA2 meets the second gate sidewall GTW2 and which is most adjacent to the third separation sidewall SPW3.

In a plan view of FIG. 2, the first impurity region IA1 may have a first center CT1, and the first center CT1 may be identical to a center of the first active protrusion AP1. The second impurity region IA2 has a second center CT2, and the second center CT2 may be identical to a center of the second active protrusion AP2. The third straight line L3 connecting the first center CT1 and the second center CT2 may not be parallel to the first direction X and the second direction Y. An angle formed by the third straight line and an axis in the first direction may be a third angle θ₃. The third angle θ₃ may be an acute angle smaller than 90° and greater than 0°. According to an embodiment, the third straight line L3 may be not parallel to either the first straight line L1 or the second straight line L2. That is, the third angle θ₃ formed together with the axis in the first direction may be different from the first angle θ₁ and the second angle θ₂.

One of the first impurity region IA1 and the second impurity region IA2 may include a source region, and the other one may include a drain region. The gate electrode GE, the gate insulating film GI, the first impurity region IA1, and the second impurity region IA2 may construct a transistor, and the semiconductor device 100 of the inventive concept may be implemented as a transistor having a source region and a drain region of an asymmetrical structure.

When a voltage is applied to one of the first impurity region IA1 and the second impurity region IA2 and the gate electrode GE, electrons or holes construct a channel region CH and moves to the first impurity region IA1 or the second impurity region IA2. Here, a majority of the channel region CH may be formed between the first straight line L1 and the second straight line L2 in the active center portion CP, and the electrons or holes moving through the channel region CH are not in contact with the separation sidewalls (i.e., the first separation sidewall SPW1 and the second separation sidewall SPW2).

The transistor illustrated in FIGS. 1 to 5 may correspond to at least one of the reset transistor, the source follower transistor, or the selection transistor of the image sensor. The gate electrode GE may include gate electrodes of the aforementioned transistors.

Compared with existing transistors arranged in active regions having a rectangular shape, the transistor in the semiconductor device 100 illustrated in FIGS. 1 to 5 may have an increased channel length, and thus may be more advantageous in a view of off-current.

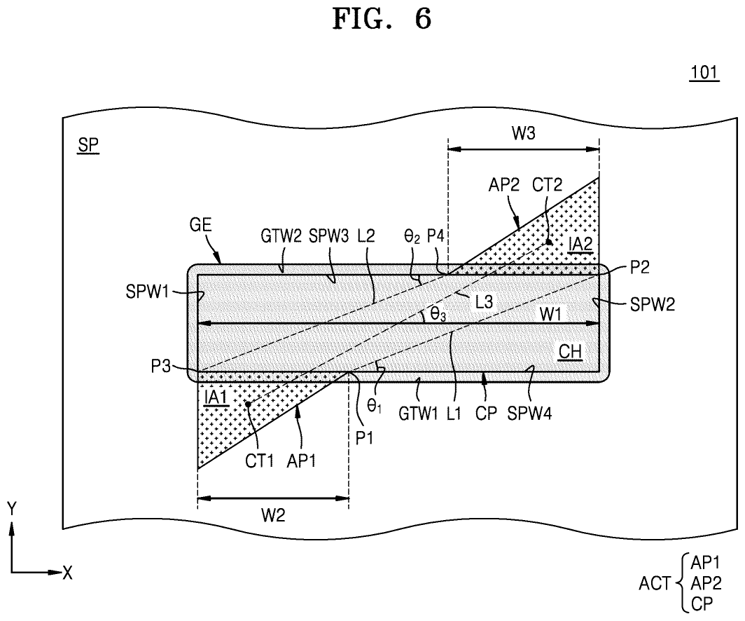

FIG. 6 is a top-plan view of a semiconductor device 101 included in an image sensor according to another embodiment. As the semiconductor device 101 illustrated in FIG. 6 has same configurations as configurations of the semiconductor device 100 illustrated in FIG. 2, except the form of active protrusions, differences between the semiconductor device 101 and the semiconductor device 100 will be mainly described.

Each of the active protrusions of the semiconductor device 100 illustrated in FIG. 2 may have a rectangular shape. Compared with this, according to another embodiment, the first active protrusion AP1 and the second active protrusion AP2 of the semiconductor device 101 may each have a right-angled triangle shape (e.g., FIG. 6). In further detail, the first active protrusion AP1 and the second active protrusion AP2 may each have a right-angled triangle shape that has a side being in contact with the active center portion CP as a base line. As the shape of the active protrusions changes due to such structure, the flexibility of arrangement and design of the active region in the semiconductor device 101 may be improved, and more particularly, it is possible to improve the electric characteristics of the device and implement efficient use of spaces.

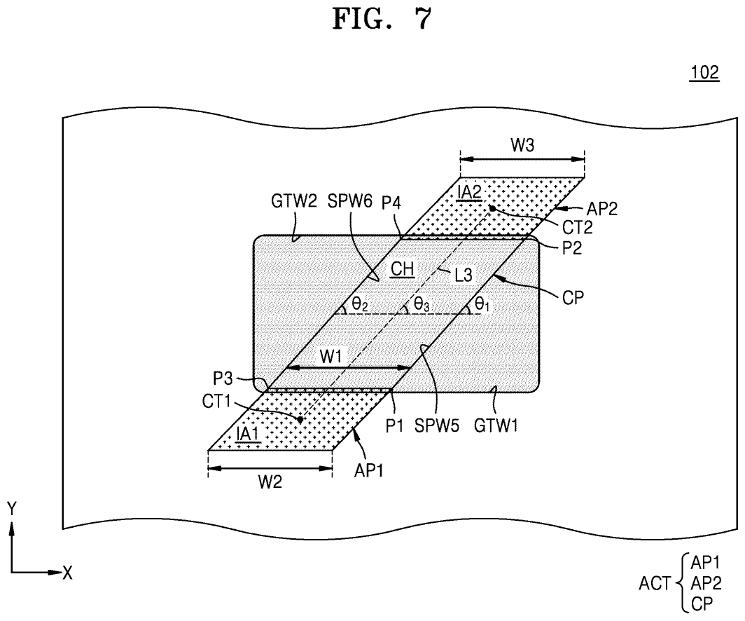

FIG. 7 is a top-plan view of a semiconductor device 102 included in an image sensor according to another embodiment. As the semiconductor device 102 illustrated in FIG. 7 is different from the semiconductor device 100 illustrated in FIG. 2, and the semiconductor device 101 illustrated in FIG. 6, hereinafter, more detailed descriptions will be given about the differences.

The semiconductor device 102 illustrated in FIG. 7 may include a device separator defining the active region ACT having an asymmetry structure. Unlike active regions in existing transistors, which are generally constructed in a rectangular shape, the active region ACT according to the present embodiment may have a parallelogram shape. More particularly, the active region ACT may form a laterally asymmetrical structure in the first direction X, and may also have an asymmetrical structure with reference to the second direction Y orthogonal to the first direction X, as well as the first direction X.

The active region ACT may include the active center portion CP, the first active protrusion AP1 arranged at one side of the active center portion CP, and the second active protrusion AP2 arranged at the other side of the active center portion CP. The active center portion CP, the first active protrusion AP1, and the second active protrusion AP2 may each have a parallelogram shape. In addition, the first impurity region IA1 may have the first center CT1, and the first center CT1 may be identical to the center of the first active protrusion AP1. Similarly, the second impurity region IA2 has the second center CT2, and the second center CT2 may be identical to the center of the second active protrusion AP2. The third straight line L3 connecting the first center CT1 and the second center CT2 may be not parallel to either the first direction X or the second direction Y.

The device separator SP may have a fifth separation sidewall SPW5 and a sixth separation sidewall SPW6 which are in contact with the active center portion CP and parallel to the third straight line L3. The angle formed by the third straight line L3 and the axis in the first direction may be the third angle θ₃. Angles formed by the axis in the first direction together with the fifth separation sidewall SPW5 and the sixth separation sidewall SPW6 may be the first angle θ₁ and the second angle θ₂, respectively. As the fifth separation sidewall SPW5 and the sixth separation sidewall SPW6 are parallel to the third straight line L3, in FIG. 7, the first angle θ₁ and the second angle θ₂ may have substantially the same size as the third angle θ₃. The third angle θ₃ may be an acute angle smaller than 90° and greater than 0°.

Further referring to the points (i.e., the first point P1, the second point P2, the third point P3, and the fourth point P4), the active region ACT may have the first point P1 at which the first active protrusion AP1 meets the active center portion CP and which is most adjacent to the fifth separation sidewall SPW5. In addition, the active region ACT may have the second point P2 at which the second active protrusion AP2 meets the active center portion CP and which is most adjacent to the fifth separation sidewall SPW5. The active region ACT may have the third point P3 at which the first active protrusion AP1 meets the active center portion CP and which is most adjacent to the sixth separation sidewall SPW6, and may also have the fourth point P4 at which the second active protrusion AP2 meets the active center portion CP and which is most adjacent to the sixth separation sidewall SPW6. In addition, the first point P1 and the second point P2 may be located on the fifth separation sidewall SPW5, and the third point P3 and the fourth point P4 may be located on the sixth separation sidewall SPW6.

The active center portion CP may have the first width W1 in the first direction X, the first active protrusion AP1 may have the second width W2 in the first direction X, and the second active protrusion AP2 may have the third width W3 in the first direction X. According to the embodiment, the first active protrusion AP1 and the second active protrusion AP2 may have substantially the same shape and substantially the same size, and therefore, the second width W2 may be substantially equal to the third width W3. In addition, according to the embodiment, the first width W1 may have substantially the same size as the second width W2 and the third width W3. The first active protrusion AP1 and the second active protrusion AP2 may be arranged in a point symmetry with reference to the center of the active center portion CP.

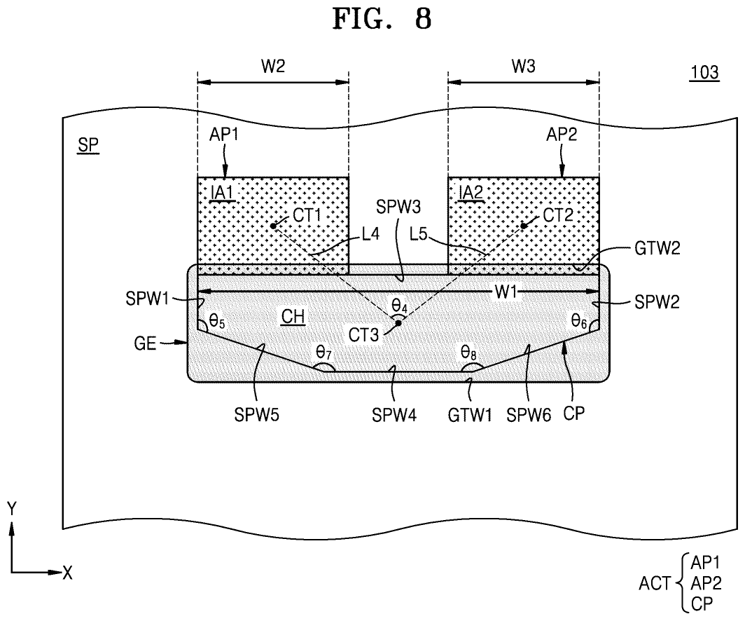

FIG. 8 is a top-plan view of a semiconductor device 103 included in an image sensor according to another embodiment.

Regarding the semiconductor device 103 illustrated in FIG. 8, differences from the semiconductor device 100 illustrated in FIG. 2, the semiconductor device 101 illustrated in FIG. 6, and the semiconductor device 102 illustrated in FIG. 7 will be mainly described.

The semiconductor device 103 illustrated in FIG. 8 may include a device separator defining the active region ACT in the asymmetrical structure. More particularly, the active region ACT may have the asymmetrical structure only with the reference to the axis in the first direction X.

The active region ACT according to an embodiment may not have a rectangular shape, i.e., a shape of active regions in general transistors, and the active region ACT illustrated in FIG. 8 may have a shape like the letter “U”. Therefore, the active region illustrated in FIG. 8 may have the asymmetrical structure only with reference to the axis in the first direction X, and may have a symmetrical structure with reference to the axis in the second direction Y orthogonal to the first direction X.

The active region ACT may have the active center portion CP, the first active protrusion AP1 arranged at a side of the active center portion CP, and the second active protrusion AP2 that is arranged at the same side of the active center portion CP as the first active protrusion AP1 but spaced apart from the first active protrusion AP1 in the first direction X. The active center portion CP, the first active protrusion AP1, and the second active protrusion AP2 may all have a rectangular shape. The first impurity region IA1 may have the first center CT1. The first center CT1 may be identical to the center of the first active protrusion AP1. The second impurity region IA2 may have the second center CT2. The second center CT2 may be identical to the center of the second active protrusion AP2. The active center portion CP may have a third center CT3.

A fourth straight line L4 connecting the first center CT1 and the third center CT3 may be not parallel to either the first direction X or the second direction Y. A fifth straight line L5 connecting the second center CT2 and the third center CT3 may be not parallel to either the first direction X or the second direction Y.

An angle formed by the fourth straight line L4 and the fifth straight line L5 may be a fourth angle θ₄. The fourth angle θ₄ may be an obtuse angle smaller than 180° and greater than 90°.

The device separator SP may have the first separation sidewall SPW1 and the second separation sidewall SPW2 which are in contact with the active center portion CP and parallel to the second direction Y. The first separation sidewall SPW1 may be adjacent to the first active protrusion AP1. The second separation sidewall SPW2 may be adjacent to the second active protrusion AP2. The device separator SP may have the third separation sidewall SPW3 and the fourth separation sidewall SPW4 which are in contact with the active center portion CP and parallel to the first direction X. The third separation sidewall SPW3 may be simultaneously adjacent to the first active protrusion AP1 and the second active protrusion AP2. The fourth separation sidewall SPW4 may be spaced apart from the first active protrusion AP1 and the second active protrusion AP2. The device separator SP may include the fifth separation sidewall SPW5 connecting the first separation sidewall SPW1 and the fourth separation sidewall SPW4. The device separator SP may include the sixth separation sidewall SPW6 connecting the second separation sidewall SPW2 and the fourth separation sidewall SPW4.

The first separation sidewall SPW1 and the fifth separation sidewall SPW5 may form a fifth angle θ₅. The second separation sidewall SPW2 and the sixth separation sidewall SPW6 may form the the sixth angle θ₆. The fifth separation sidewall SPW5 and the fourth separation sidewall SPW4 may form a seventh angle θ₇. The sixth separation sidewall SPW6 and the fourth separation sidewall SPW4 may form an eighth angle θ₈. The fifth angle θ₅ may be an obtuse angle smaller than 180° and greater than 90°. Each of the seventh angle θ₇ and the eighth angle θ₈ may be an obtuse angle smaller than 180 degrees and greater than 90 degrees. The seventh angle θ₇ and the eight angle θ₈ may have different sizes.

In FIG. 8, when a voltage is applied to one of the first impurity region IA1 and the second impurity region IA2 and the gate electrode GE2, as the electrons/holes of the second impurity region IA2 move toward the first impurity region IA1, the channel region CH is formed. Here, a majority of the channel region CH is formed in a neighboring region connecting the fourth straight line L4 and the fifth straight line L5 in the active center portion CP. That is, in FIG. 8, the channel region CH may have a shape like the letter “U”. That is, the electrons/holes moving through the channel region CH are not in contact with the separation sidewalls.

The active center portion CP may have the first width W1 in the first direction X. The first active protrusion AP1 may have the second width W2 in the first direction X. The second active protrusion AP2 may have the third width W3 in the first direction X.

In an embodiment, the first active protrusion AP1 and the second active protrusion AP2 may have substantially the same shape and substantially the same size. That is, the second width W2 of the first active protrusion AP1 may be substantially equal to the third width W3 of the second active protrusion AP2.

In an embodiment, the second width W2 may be smaller than the first width W1. The first active protrusion AP1 and the second active protrusion AP2 may be arranged in an axial symmetry with reference to an axis in the second direction Y passing the center of the active center portion CP.

By forming a polygon shape by cutting a portion of the active region in the semiconductor device as illustrated in FIGS. 2 to 8, regarding a reset gate floating diffusion region RGFD (see FIG. 10), degree of freedom of patterning may be improved, or a margin for securing a width may be obtained. Detailed description thereof will be given with reference to FIG. 10.

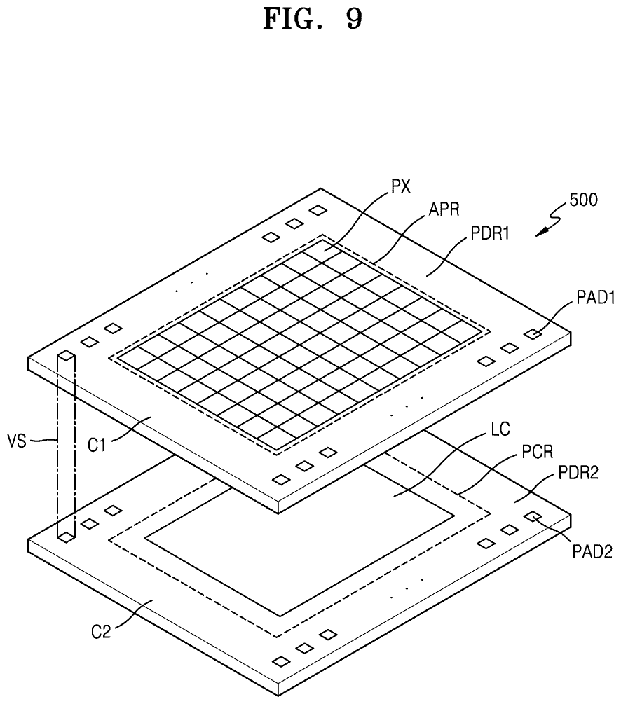

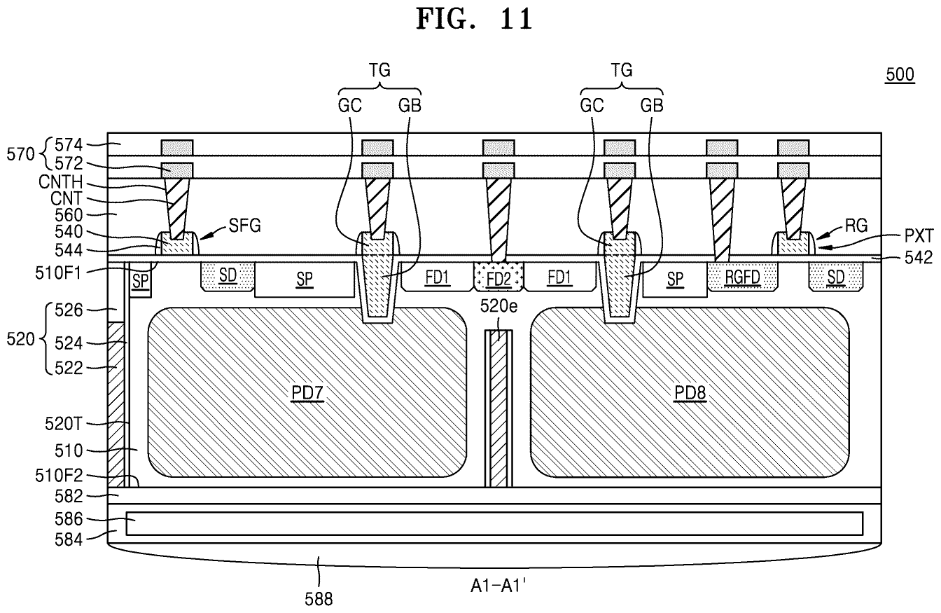

FIG. 9 is a layout diagram illustrating an image sensor 500 according to an embodiment. FIG. 10 is a top-plan view of the image sensor 500 according to an embodiment, which illustrates a portion of an active pixel region APR. FIG. 11 is a cross-sectional view taken along line A1-A1′ shown in FIG. 10.

Referring to FIGS. 9 to 11, the image sensor 500 may include a stack image sensor including a first chip C1 and a second chip C2 stacked in the vertical direction. The first chip C1 may include the active pixel region APR and a first pad region PDR1, and the second chip C2 may include a peripheral circuit region PCR and a second pad region PDR2.

A plurality of first pads PAD1 in the first pad region PDR1 may be configured to transmit/receive electric signals to/from external devices and the like. The peripheral circuit region PCR may include a logic circuit block LC and a plurality of complementary metal-oxide semiconductor (CMOS) transistors. The peripheral circuit region PCR may provide a certain signal to each active pixel PX in the active pixel region APR or control an output signal from the each active pixel PX. The first pads PAD1 in the first pad region PDR1 may be electrically connected to second pads PAD2 in the second pad region PDR2 through via structures VS.

The active pixel region APR may include a plurality of pixels PX, and a plurality of photoelectric transformation regions PD (e.g., PD1 through PD8 in FIG. 10) may be arranged in each of the plurality of pixels PX. In the active pixel region APR, the plurality of pixels PX may be arranged in the form of a matrix forming rows and columns in the first direction X parallel to a top surface of a substrate 510 and the second direction Y perpendicular to the first direction X and parallel to the top surface of the substrate 510. The substrate 510 illustrated in FIG. 11 may correspond to the substrate SB illustrated in FIGS. 3 to 5.

The substrate 510 may include a first surface 510F1 and a second surface 510F2 opposite to each other. Here, for convenience, a surface of the substrate 510, on which a color filter 586 is arranged, is referred to as the second surface 510F2, and a surface opposite to the second surface 510F2 is referred to as the first surface 510F1. However, the inventive concept is not limited thereto.

In embodiments, the substrate 510 may include a p-type substrate. For example, the substrate 510 may include any one of Si, Ge, SiGe, SiC, GaAs, InAs, or InP. For example, the substrate 510 may include a p-type silicon substrate. In embodiments, the substrate 510 may include a p-type bulk substrate and a p-type or n-type epitaxial layer being grown on the p-type bulk substrate. In other embodiments, the substrate 510 may include an n-type bulk substrate and a p-type or n-type epitaxial layer being grown on the n-type bulk substrate. Alternatively, the substrate 510 may include an organic plastic substrate. A well region may be arranged in the substrate 510 adjacent to the first surface 510F1 of the substrate 510. The well region may be a region doped with a p-type impurity.

In the active pixel region APR, the plurality of pixels PX may be arranged in the form of a matrix in the substrate 510. The plurality of photoelectric transformation region PD may be arranged in each of the plurality of pixels PX. The plurality of photoelectric transformation regions PD may be regions in which light incident from the second surface 510F2 of the substrate 510 is converted into an electric signal. The plurality of photoelectric transformation regions PD may be regions including an n-type impurity.

In the active pixel region APR, a pixel separator 520 may be arranged in the substrate 510, and the plurality of pixels PX may be defined by the pixel separator 520. The plurality of photoelectric transformation region PD may be arranged in a pixel PX surrounded by the pixel separator 520. For example, as illustrated in FIGS. 10 to 12, each one pixel may include a first sub-pixel region and a second sub-pixel region. In an embodiment, a first pixel region PX1 may include a first sub-pixel region SPX1a and a second sub-pixel region SPX1b. In an embodiment, a second pixel region PX2 may include a first sub-pixel region SPX2a and a second sub-pixel region SPX2b. In an embodiment, a third pixel region PX3 may include a first sub-pixel region SPX3a and a second sub-pixel region SPX3b. In an embodiment, a fourth pixel region PX4 may include a first sub-pixel region SPX4a and a second sub-pixel region SPX4b. The pixels may include different types of first sub-pixel regions and second sub-pixel regions.

Photoelectric transformation regions may be arranged in each of the first sub-pixel region and the second sub-pixel region. In an embodiment, a first photoelectric transformation region PD1 and a second photoelectric transformation region PD2 may be arranged in the first sub-pixel region SPX1a and the second sub-pixel region SPX1b included in the first pixel region PX1. In an embodiment, a third photoelectric transformation region PD3 and a fourth photoelectric transformation region PD4 may be arranged in the first sub-pixel region SPX2a and the second sub-pixel region SPX2b included in the second pixel region PX2. In an embodiment, a fifth photoelectric transformation region PD5 and a sixth photoelectric transformation region PD6 may be arranged in the first sub-pixel region SPX3a and the second sub-pixel region SPX3b included in the third pixel region PX3. In an embodiment, a seventh photoelectric transformation region PD7 and an eighth photoelectric transformation region PD8 may be arranged in the first sub-pixel region SPX4a and the second sub-pixel region SPX4b included in the fourth pixel region PX4.

A floating diffusion region FD may be arranged in a center region of a pixel PX. The first sub-pixel region and the second sub-pixel region included in each pixel may share one floating diffusion region FD, and two photoelectric transformation regions PD may be arranged adjacent to the floating diffusion region FD. That is, two photoelectric transformation regions PD may construct one pixel.

The active region illustrated in FIG. 10 may include a first active region ACT1, a second active region ACT2, a third active region ACT3, and a fourth active region ACT4, and these active regions may be configured as separate regions distinguished from one another. At least one of the first active region ACT1, the second active region ACT2, the third active region ACT3, or the fourth active region ACT4 may have a different shape and be simultaneously driven by a separate transistor that independently operates. However, gate electrodes GE located near the active regions (i.e., the first active region ACT1, the second active region ACT2, the third active region ACT3, and the fourth active region ACT4) may be configured to have a same structure and a same shape.

According to an embodiment, the first active region ACT1 may be arranged near a reset gate RG. More particularly, referring to FIG. 10, the image sensor 500 may include a first reset gate RG1, a second reset gate RG2, and a third reset gate RG3. In addition, according to another embodiment, the second active region ACT2 may be arranged near a dummy gate DMG, the third active region ACT3 may be arranged near a selection gate SEL, and the fourth active region ACT4 may be arranged near a source follower gate SFG.

One or more of the first active region ACT1, the second active region ACT2, the third active region ACT3, and the fourth active region ACT4 may include a combination of one or more of shapes of the semiconductor devices 100, 101, 102, and 103, and various forms described with reference to FIGS. 1 to 8.

A plurality of transmission gates TG may be arranged near the photoelectric transformation regions, and each of the plurality of transmission gates TG may extend toward the floating diffusion region FD in different directions to form a transmission path of electrical charge.

To further describe an inner portion of each pixel region, the plurality of photoelectric transformation regions arranged in each pixel region may be distinctively arranged at two sides of lateral extending portions 520e. In addition, the floating diffusion region FD may be arranged in a space between the lateral extending portions 520e facing each other in one pixel region, thereby enabling efficient movement of electric charge.

In the first active region ACT1, the reset gate floating diffusion region RGFD may be arranged near the transmission gate of the active protrusion. By implementing the shape of the active region in the form described with reference to FIGS. 1 to 8, a margin more flexible than a margin in an existing structure may be provided for securing a width W_RGFD of the reset gate floating diffusion region RGFD. That is, as the reset gate floating diffusion region RGFD is arranged at a certain interval from the transmission gate TG, the width W_RGFD of the corresponding region may be sufficiently secured.

Further referring to FIG. 11, the pixel separator 520 may be formed in a pixel trench 520T that is formed to pass through the first surface 510F1 of the substrate 510 to the second surface 510F2 of the substrate 510. The pixel separator 520 may include a pixel separator insulating layer 522 conformally formed on a sidewall of the pixel trench 520T, a conductive layer 524 filled on the pixel separator insulating layer 522, and an upper insulating layer 526 formed thereon.

According to an embodiment, the pixel separator insulating layer 522 may include a metal oxide such as hafnium oxide, aluminum oxide, and tantalum oxide, and such configuration may function as a negative fixed charge layer. However, the inventive concept is not limited to such configuration, and in another embodiment, the pixel separator insulating layer 522 may include various insulating materials such as silicon oxide, silicon nitride, or silicon oxynitride. In addition, the conductive layer 524 may include at least one of doped polysilicon, a metal, a metal silicide, a metal nitride, or a metal-containing film.

In embodiments, the pixel separator 520 may include the lateral extending portions 520e extending in the first direction X and the second direction Y toward the center portions of the first to fourth pixel regions PX1, PX2, PX3, and PX4. The lateral extending portions 520e may be arranged between two sub-pixel regions arranged in the first direction X. However, the direction in which the lateral extending portions 520e extend is not limited to the first direction and may vary according to a direction of the sub-pixel regions. In an embodiment, the lateral extending portions 520e may be arranged between two sub-pixel regions arranged in the second direction Y.

In embodiments, the lateral extending portions 520e arranged in the center region of the pixel PX may extend from the second surface 510F2 of the substrate 510 to a level lower than the first surface 510F1 of the substrate 510 without completely passing through the substrate 510. Accordingly, the lateral extending portions 520e arranged in the center region of the pixel PX may vertically overlap the second floating diffusion region FD2 arranged adjacent to the first surface 510F1 of the substrate 510 in the center region of the pixel PX.

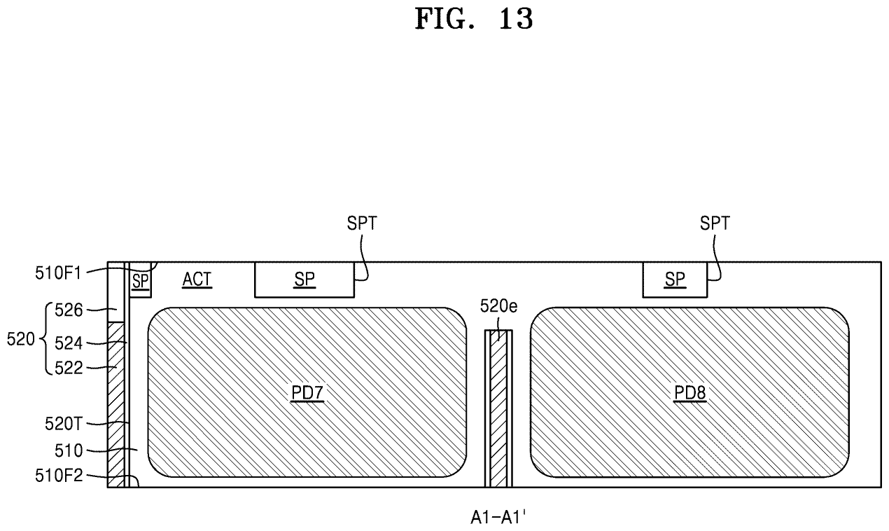

As illustrated in FIG. 11, the device separator SP defining the active region ACT may be formed on the first surface 510F1 of the substrate 510, the device separator SP may be arranged in a device separation trench SPT (see FIG. 13) formed in a preset depth on the first surface 510F1 of the substrate 510 and include an insulating material.

Pixel transistors PXT included in a pixel circuit may be arranged on the active region ACT, and such pixel transistors PXT may include the source follower gate SFG, the selection gate SEL, and the reset gate RG. In addition, a ground region RND and the floating diffusion region FD defined by the device separator SP may be formed in the substrate 510, and the ground region GND, the floating diffusion region FD, and the active region ACT may be spaced apart from one another by the device separator SP.

According to some embodiments, as illustrated in FIG. 10, the first pixel region PX1, the second pixel region PX2, the third pixel PX3, and the fourth pixel PX4 may be arranged in the form of a matrix on the surface of the substrate. In addition, the first pixel region PX1, the second pixel region PX2, the third pixel region PX3, and the fourth pixel region PX4 are respectively divided into the first sub-pixel regions SPX1a, SPX2a, SPX3a, and SPX4a and the second sub-pixel regions SPX1b, SPX2b, SPX3b, and SPX4b, and the sub-pixel regions may also be arranged in the form of a matrix on the surface of the substrate.

According to some embodiments, the first pixel region PX1 may include the dummy gate DMG and the selection gate SEL, and the second pixel region PX2 may include the reset gate RG. In addition, the third pixel region PX3 may include the dummy gate DMG and the source follower gate SFG, and the fourth pixel region PX4 may include the source follower gate SFG and the reset gate RG. However, the structure illustrated in FIG. 10 is only an example of a layout of the transistors according to some embodiments, and an actual layout of the transistors or the shape of the active region is not limited thereto and may be implemented in various forms.

In embodiments, the transmission gate TG may construct a transmission transistor, and the transmission transistor may be configured to transmit the electric charge, which is generated from two photoelectric transformation regions included in one pixel region, to the floating diffusion region FD. The reset gate RG may construct the reset transistor, and the reset transistor may be configured to periodically reset the electric charge stored in the floating diffusion region FD. The source follower gate SFG may construct the source follower transistor SF (see FIG. 7), and the source follower transistor SF may be configured to function as a source follower buffer amplifier and buffer a signal according to the electric charge charged in the floating diffusion region. The selection gate SEL may construct the selection transistor, and the selection transistor may be configured to perform switching and addressing for selecting the pixel region PX.

The pixel transistor PXT may include a gate insulating layer 542 arranged on the first surface 510F1 of the substrate 510, a gate electrode 540 arranged on the gate insulating layer 542, and a source/drain region SD. A spacer 544 may be arranged on a sidewall of the gate electrode 540. The source/drain region SD may be arranged in the substrate 510 arranged at a side portion of the gate electrode 540. According to an embodiment, regarding the reset gate RG, the reset gate floating diffusion region RGFD may be arranged in the substrate 510 arranged at a side of the gate electrode 540.

In embodiments, the gate electrode 540 may include at least one of doped polysilicon, a metal, a metal silicide, a metal nitride, or a metal-containing film. The gate insulating layer 542 may include silicon oxide or a metal oxide. The source/drain region SD may include a region doped with an n-type impurity.

The transmission gate TG may have a vertical buried-gate structure, e.g., a dual-type buried-gate structure. As the transmission gate TG has a dual-type buried-gate structure, an area of an efficient channel between the substrate 510 and the transmission gate TG may increase. In embodiments, the transmission gate TG may include a buried gate TGB and a gate connector GC, and the buried gate GB may be arranged to extend in the vertical direction into the substrate 510.

As illustrated in FIG. 11, bottom portions of the buried gate GB may be surrounded by the photoelectric transformation region PD. The gate insulating layer 542 may extend from the first surface 510F1 of the substrate 510 onto an inner wall of the buried gate GB.

A top surface of the buried gate GB may be arranged at a level higher than the first surface 510F1 of the substrate 510.

The gate connector GC may be integrally connected to the buried gate GB. In embodiments, the gate connector GC may be arranged on the buried gate GB, and a top surface of the gate connector GC may be arranged at a level higher than the top surface of the buried gate. A bottom surface of the gate connector GC may be arranged at a vertical level higher than a bottom surface of the buried gate GB and be in contact with a top surface of the gate insulating layer 542.

The spacer 544 may be arranged on a sidewall of the transmission gate TG. The spacer 544 may be arranged on a sidewall of the gate connector GC that is arranged at a level higher than the first surface 510F1 of the substrate 510. A bottom surface of the spacer 544 may be in contact with the top surface of the gate insulating layer 542 and arranged to surround the entire portion of the sidewall of the transmission gate TG arranged at a level higher than the first surface 510F1 of the substrate 510. According to an embodiment, the spacer 544 may be arranged to surround the entire portion of the sidewall of the gate electrode 540 included in the source follower gate SFG and the reset gate RG, as well as the transmission gate.

The floating diffusion region FD may be spaced apart in a horizontal direction (e.g., the first direction X in FIG. 1) from the sidewall of the transmission gate TG (e.g., a sidewall of the buried gate GB) on a side of the transmission gate TG.

In embodiments, the floating diffusion region FD may include the first floating diffusion region FD1 and the second floating diffusion region FD2. The second floating diffusion region FD2 may be arranged in the center region of the pixel PX and shared by the first sub-pixel region and the second sub-pixel region. The first floating diffusion region FD1 may be arranged between the second floating diffusion region FD2 and the transmission gate TG. For example, the first floating diffusion region FD1, which is arranged in the first sub-pixel region and the second sub-pixel region, may include a rectangular plane shape arranged adjacent to the second floating diffusion region FD2 and extending toward the center of the second floating diffusion region FD2.

As illustrated in FIG. 11, the first floating diffusion region FD1 may be spaced apart from a sidewall of the buried gate GB.

A buried insulating layer 560 may be arranged on the first surface 510F1 of the substrate 510. The buried insulating layer 560 may cover the floating diffusion region FD, the device separator SP, the gate electrode 540, the transmission gate TG, the reset gate RG, and the source follower gate SFG. In embodiments, the buried insulating layer 560 may include silicon nitride and silicon oxynitride.

A contact CNT penetrating the buried insulating layer 560 may be arranged on the first surface 510F1 of the substrate 510. For example, the contact CNT may penetrate the buried insulating layer 560 and be electrically connected to the active region ACT, the transmission gate TG, and the gate electrode 540. Here, the active region may construct the first active region ACT1, the second active region ACT2, the third active region ACT3, and the fourth active region ACT4, as illustrated in FIG. 10.

In embodiments, one contact CNT may be arranged on a top surface of the transmission gate TG. The contact CNT may be arranged at a position vertically overlapping the gate connector GC.

An upper wiring structure 570 may be arranged on the buried insulating layer 560. The upper wiring structure 570 may include a stack structure including a plurality of layers. The upper wiring structure 570 may include a wiring layer 572 and a wiring insulating layer 574 surrounding the wiring layer 572. The wiring layer 572 may include at least one of polysilicon doped or not doped with impurities, a metal, a metal silicide, a metal nitride, or a metal-containing film. For example, the wiring layer 572 may include tungsten, aluminum, copper, tungsten silicide, titanium silicide, tungsten nitride, titanium nitride, doped polysilicon, and the like. The wiring insulating layer 574 may include an insulating material such as silicon oxide, silicon nitride, silicon oxynitride, and the like.

A back-surface insulating layer 582 may be arranged on the second surface 510F2 of the substrate 510. The back-surface insulating layer 582 may be arranged substantially on the entire area of the second surface 510F2 of the substrate 510. In embodiments, the back-surface insulating layer 582 may include a metal oxide such as hafnium oxide, aluminum oxide, tantalum oxide, and the like. In other embodiments, the back-surface insulating layer 582 may include an insulating material such as silicon oxide, silicon nitride, silicon oxynitride, a low-permittivity material, and the like.

A passivation layer 584 may be arranged on the back-surface insulating layer 582, and a color filter 586 and a microlens 588 may be arranged on the passivation layer 584. Alternatively, a supporting substrate (not shown) may be further arranged on the first surface 510F1 of the substrate 510.

FIG. 12 is a top-plan view of an image sensor 501 according to another embodiment. Differences from the image sensor 500 in FIG. 10 will be mainly described.

Each of the transmission gates TG included in the image sensor 501 in FIG. 12 may be connected to word lines WL1 and WL2. Each of the transmission gates TG may extend in a direction opposite to a direction toward the active region ACT. In an embodiment, each of the transmission gates TG in FIG. 12 may extend toward the pixel separator 520 in each pixel region. Each of the transmission gates TG may not extend toward the floating diffusion region FD, i.e., the center of each pixel region.

FIGS. 13 to 20 are cross-sectional views illustrating a method of manufacturing an image sensor, according to an embodiment.

Referring to FIG. 13, the substrate 510 is provided. The photoelectric transformation regions PD may be formed in the substrate 510 through an ion injection process.

Next, the pixel separator 520 extending from the first surface 510F1 of the substrate 510 into the substrate 510 may be formed. The pixel separator 520 may include the lateral extending portions 520e, and the lateral extending portions 520e may not be formed from the first surface 510F1 of the substrate 510 to a certain height in the center region of the pixel PX.

Next, a device separator trench SPT may be formed by removing a portion of the first surface 510F1 of the substrate 510, and the device separator SP may be formed by filling the device separator trench SPT with an insulating material.

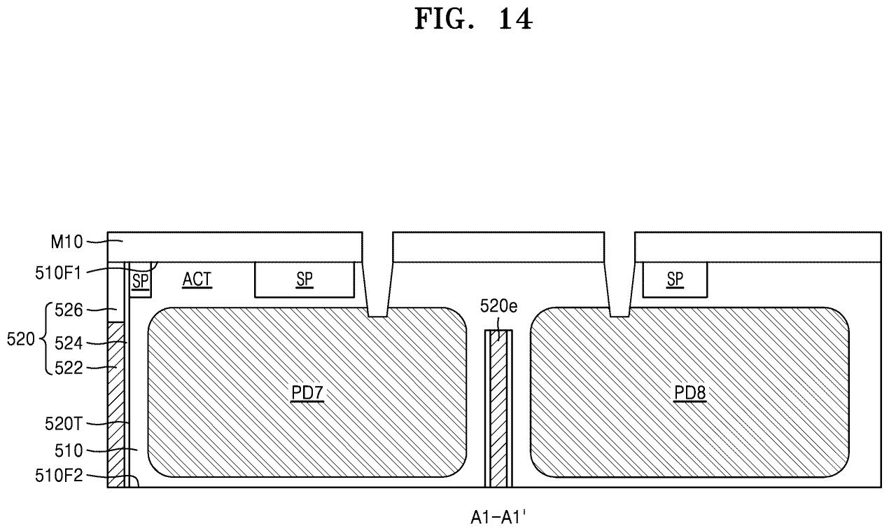

Referring to FIG. 14, a first mask M10 may be formed on the first surface 510F1 of the substrate 510, and buried gate openings extending from the first surface 510F1 of the substrate 510 into the substrate 510 may be formed by using the first mask M10 as an etch mask.

The buried gate openings may be arranged adjacent to the preliminary floating diffusion region, and bottom portions of the buried gate openings may be surrounded by the photoelectric transformation regions PD.

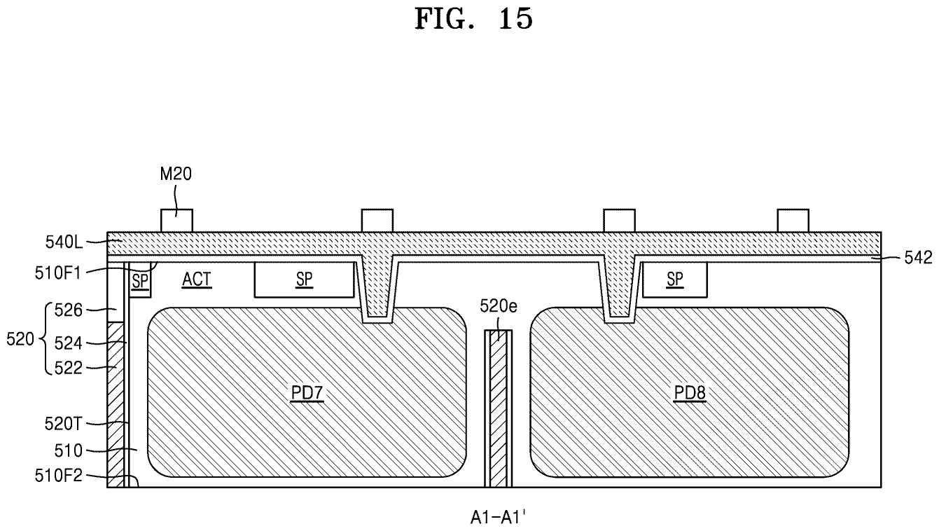

Referring to FIG. 15, the first mask M10 may be removed. Next, the gate insulating layer 542 may be formed on the first surface 510F1 of the substrate 510 and on an inner wall of the buried gate openings.

Next, a gate electrode layer 540L filling the buried gate openings may be formed on the gate insulating layer 542. The gate electrode layer 540L may be formed in a great thickness sufficient to fill the buried gate openings. Next, a second mask M20 may be formed on the gate electrode layer 540L.

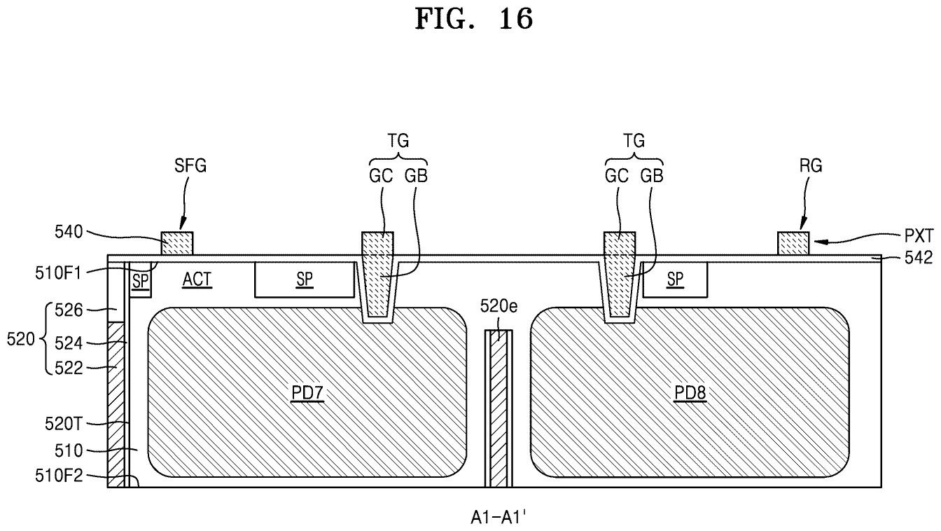

Referring to FIG. 16, the gate electrode 540 may be formed by patterning the gate electrode layer 540L by using the second mask M20 as an etch mask. The gate electrode 540 may construct the transmission gate TG, the source follower gate SFG, and the reset gate RG.

In embodiments, the transmission gate TG may include a buried gate GB arranged in the buried gate opening and the gate connector GC arranged on the buried gate GB.

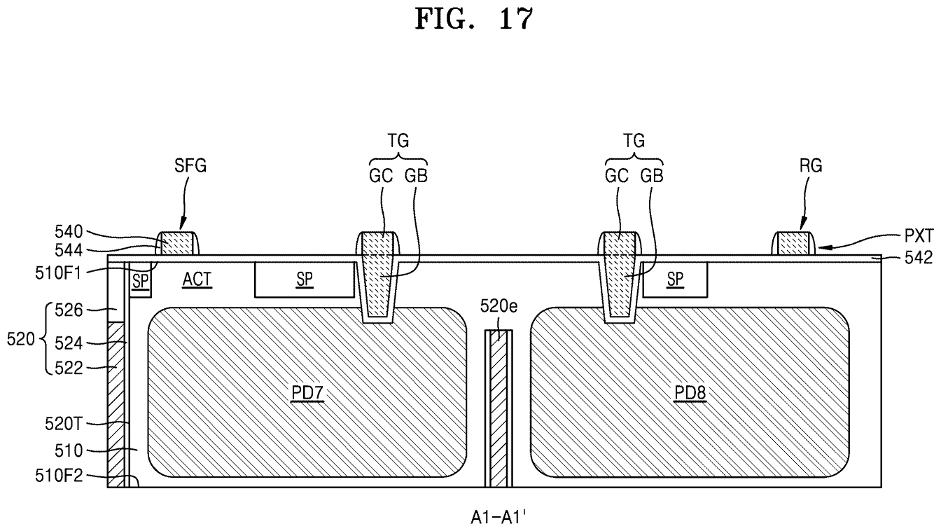

Referring to FIG. 17, an insulating layer (not shown) covering the gate electrode 540 and the transmission gate TG may be formed on the gate insulating layer 542, and the spacer 544 may remain on sidewalls of the gate electrode 540 and the transmission gate TG by performing an anisotropic etching process on the insulating layer.

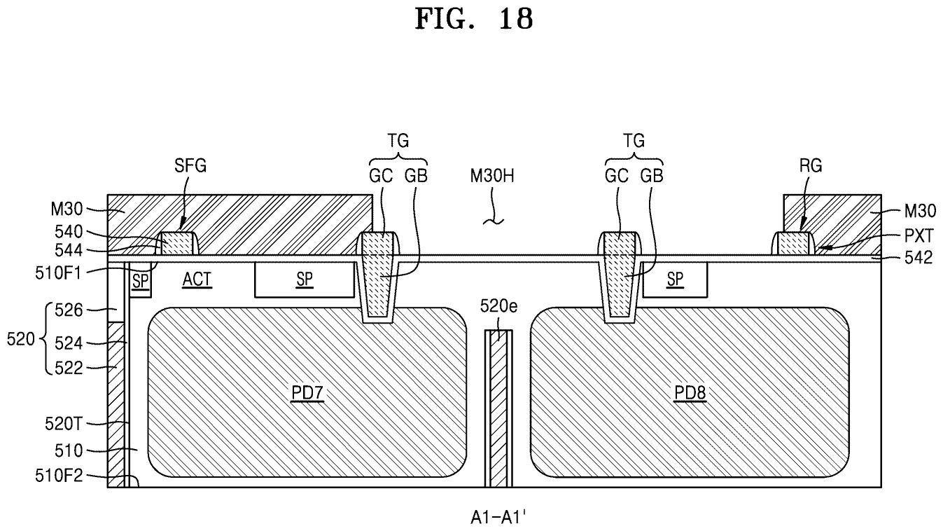

Referring to FIG. 18, an ion injection mask M30 covering the gate electrode 540 and the transmission gate TG may be formed on the first surface 510F1 of the substrate 510. The ion injection mask M30 may have an opening M30H exposing a periphery of the center region of the pixel. The opening M30H may be arranged to vertically overlap the plurality of transmission gates TG, the spacer 544, and the preliminary floating diffusion region.

As a size of the opening M30H of the ion injection mask M30 is relatively great, patterning defects in a process of forming the ion injection mask M30 may be prevented.

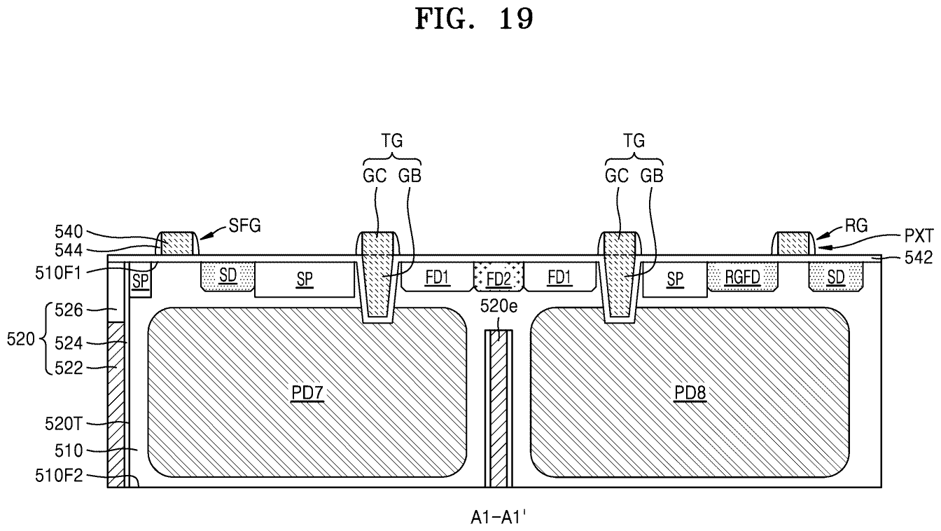

Referring to FIG. 19, the first floating diffusion region FD1 and the second floating diffusion region FD2 may be formed by injecting dopants in regions exposed by the opening M30H of the ion injection mask M30. The first floating diffusion region FD1 and the second floating diffusion region FD2 may have relatively different dopant levels, and ion injection processes for forming the first floating diffusion region FD1 and the second floating diffusion region FD2 may be sequentially performed.

According to embodiments, dopants may be not injected into the substrate 510 covered by the plurality of transmission gates TG and the spacer 544, and accordingly, an intrinsic semiconductor region may be formed around the plurality of transmission gates TG.

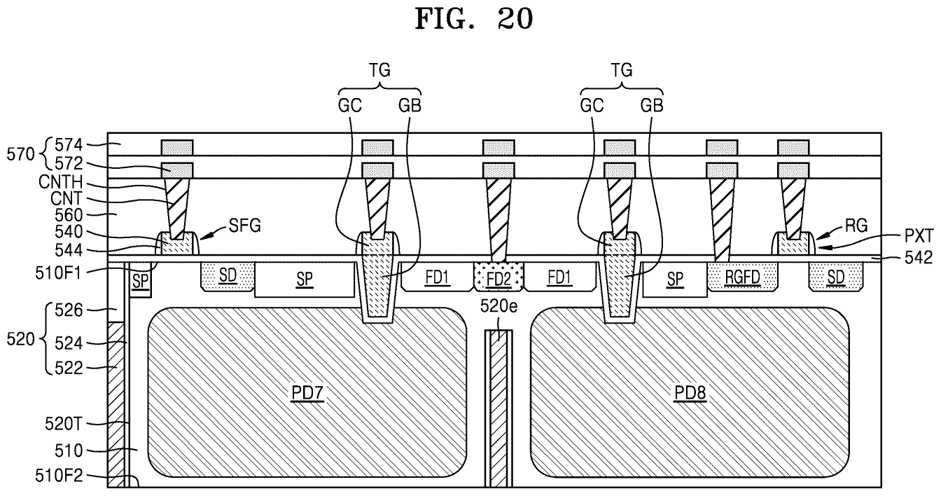

Referring to FIG. 20, the ion injection mask M30 may be removed. Next, the buried insulating layer 560 covering the gate electrode 540 and the transmission gate TG may be formed on the gate insulating layer 542. Next, the contact CNT penetrating the buried insulating layer 560 and electrically connected to the active region ACT, the transmission gate TG, and the gate electrode 540 may be formed. The contact CNT may be formed in a contact hole CNTH.

Referring again to FIG. 11, some of a thickness of the second surface 510F2 of the substrate 510 may be removed, the back-surface insulating layer 582 and the passivation layer 584 may be formed on the second surface 510F2 of the substrate 510, and the color filter 586 and the microlens 588 may be formed on the passivation layer 584.

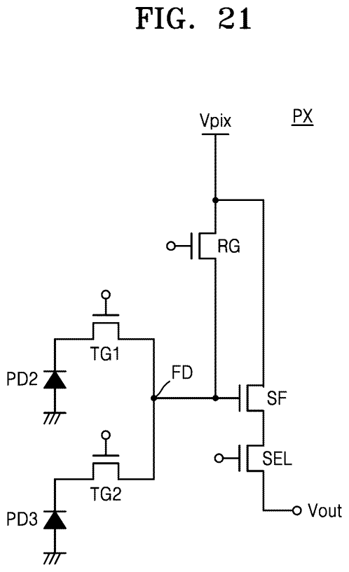

FIG. 21 is an equivalent circuit diagram of a pixel in an image sensor according to an embodiment.

Referring to FIG. 21, the pixel PX described with reference to the drawing may correspond to one of the first pixel region PX1, the second pixel region PX2, the third pixel region PX3, and the fourth pixel region PX4 in FIG. 12. As described above, the gates included in the sub-pixel regions constructed by each pixel region may vary according to arrangements. In addition, the description that one pixel has a 2PD type including two photoelectric transformation regions is identical to the description given above.

The plurality of pixels PX may be arranged in the form of a matrix. Each of the plurality of pixels PX may include a transmission transistor, including the transmission gates TG1 and TG2, and logic transistors. Here, the logic transistors may include a reset transistor including the reset gate RG, a selection transistor including the selection gate SEL, and a source follower transistor including the source follower gate SFG. For convenience, only in the present drawing, the reset transistor will be referred to as RG, the transmission transistors will be referred to as TG1 and TG2, the selection transistor will be referred to as SEL, and the source follower transistor will be referred to as SF.

Each of the plurality of pixels PX may further include the photoelectric transformation regions PD1 and PD2 and the floating diffusion region FD. The first photoelectric transformation region PD1 and the second photoelectric transformation region PD2 may generate and charge photocharge in proportion to an amount of light incident from outside, and a photo diode, a photo transistor, a photogate, a pinned photo diode (PPD), and combinations thereof may be used.

The transmission transistor TG may be configured to transmit charges generated in the first photoelectric transformation region PD1 and the second photoelectric transformation region PD2 to the floating diffusion region FD. The floating diffusion region FD may be configured to receive the charges generated in the first photoelectric transformation region PD1 and the second photoelectric transformation region PD2 and accumulatively store the charges. The source follower transistor SF may be controlled according to an amount of the photocharge accumulated in the floating diffusion region FD.

The reset transistor RG may periodically reset the electric charge accumulated in the floating diffusion region FD. A drain electrode of the reset transistor RG is connected to the floating diffusion region FD and a source electrode of the reset transistor RG is connected to a power voltage Vₚᵢₓ. When the reset transistor RG is turned on, the power voltage Vₚᵢₓ connected to the source electrode of the reset transistor RG is delivered to the floating diffusion region FD. When the reset transistor RG is turned on, the charge accumulated in the floating diffusion region FD may be discharged, and the floating diffusion region FD may be reset.

The source follower transistor SF is connected to a current source (not shown) located outside the plurality of pixel PX and functions as a source follower buffer amplifier, amplifies a potential change in the floating diffusion region FD and outputs the amplified potential change through the output line V_{OUT}.

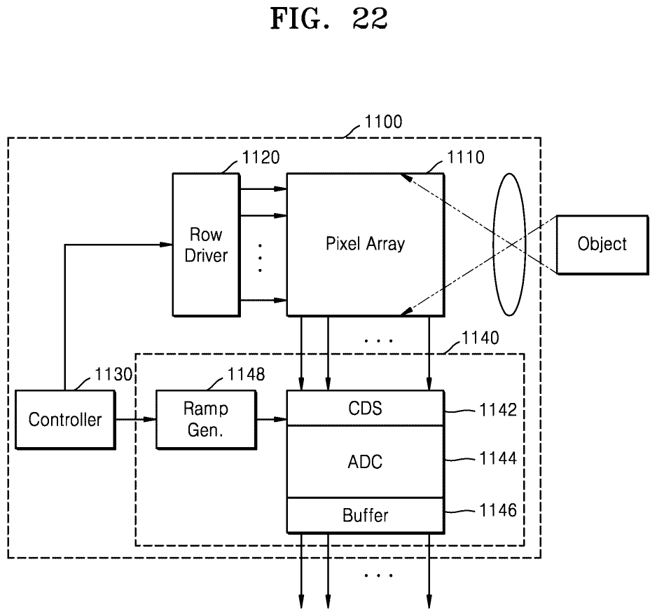

FIG. 22 is a block diagram illustrating a configuration of an image sensor 1100 according to an embodiment.

Referring to FIG. 22, the image sensor 1100 may include a pixel array 1110, a controller 1130, a row driver 1120, and a pixel signal processor 1140. The image sensor 1100 includes at least one of the image sensor 500 or the image sensor 501 described with reference to FIGS. 1 to 12.

The pixel array 1110 may include a plurality of unit pixels two-dimensionally arranged, and each of the unit pixels may include a photoelectric transformation element. The photoelectric transformation element may be configured to absorb light and generate an electric charge, and an electric signal (an output voltage) according to the generated electric charge may be provided to the pixel signal processor 1140 through a vertical signal line. The unit pixels included in the pixel array 1110 may provide the output voltage one by one in a row unit, and accordingly, the unit pixels in a row of the pixel array 1110 may be simultaneously activated in response to a selection signal output from the row driver 1120. The unit pixels in a selected row may provide the output voltage according to the absorbed light to an output line in a corresponding column.

The controller 1130 may be configured to control the row driver 1120 such that the pixel array 1110 absorbs light and accumulates the electric charges, temporarily stores the accumulated electric charges, and outputs an electric signal according to the stored electric charges to the outside of the pixel array 1110. In addition, the controller 1130 may be configured to control the pixel signal processor 1140 to measure an output voltage provided by the pixel array 1110.

The pixel signal processor 1140 may include a correlated double sampler (CDS) 1142, an analog-digital converter 1144, and a buffer 1146. The CDS 1142 may be configured to sample and hold the output voltage provided from the pixel array 1110. The CDS 1142 may be configured to perform double sampling on a specific noise level and a level according to the generated output voltage and output a level corresponding to a difference therebetween. In addition, the CDS 1142 may be configured to receive ramp signals generated by a ramp signal generator 1148, compare the ramp signals, and output a result of the comparison.

The analog-digital converter 1144 may be configured to convert an analog signal, which corresponds to the level received from the CDS 1142, to a digital signal. The buffer 1146 may be configured to latch the digital signal, and the latched signal may be sequentially output outside the image sensor 1100 and delivered to an image processor (not shown).

The embodiments are only examples, and various modifications and other equivalent embodiments may be made therefrom by those skilled in the art. Accordingly, the genuine technical scope according to embodiments shall be determined according to the inventive concept defined in the following claims.

While the inventive concept has been particularly shown and described with reference to embodiments thereof, it will be understood that various changes in form and details may be made therein without departing from the spirit and scope of the following claims.

What is claimed is:

1. An image sensor comprising:
a substrate having a pixel region defined by a pixel separator;
a floating diffusion region arranged in the pixel region of the substrate;
a plurality of photoelectric transformation regions arranged around the floating diffusion region in the substrate;
a plurality of transmission gates respectively arranged adjacent to the plurality of photoelectric transformation regions, wherein the plurality of transmission gates extend toward the floating diffusion region respectively in different directions; and
a semiconductor device comprising a plurality of device separators and a gate electrode, the plurality of device separators being respectively arranged adjacent to the plurality of transmission gates and defining an active region having an asymmetrical structure with reference to a first direction and a second direction orthogonal to the first direction, and the gate electrode crossing the active region in the first direction and having a first gate sidewall and a second gate sidewall spaced apart from each other in the second direction, wherein:
the pixel separator comprises lateral extending portions extending in the first direction and the second direction toward a center portion of the pixel region, and
in a plan view,
the plurality of photoelectric transformation regions arranged in the pixel region are distinguished from each other by being arranged at two sides of the lateral extending portions in the first direction, and
the floating diffusion region is arranged in a space between the lateral extending portions arranged in the pixel region and facing each other in the second direction.

2. The image sensor of claim 1, wherein:
active regions defined by the plurality of device separators construct first through fourth active regions, and
in a plan view,
at least one of the first through fourth active regions has a shape different from others, and
gate electrodes arranged adjacent to the first through fourth active regions have a same shape.

3. The image sensor of claim 2, further comprising,
in the active region,
a first impurity region adjacent to the first gate sidewall; and
a second impurity region adjacent to the second gate sidewall, wherein:
the active region comprises:
an active center portion overlapping the gate electrode;
a first active protrusion in which the first impurity region is arranged; and
a second active protrusion in which the second impurity region is arranged, and
the first active protrusion and the second active protrusion are arranged in a point symmetry with reference to a center of the active center portion.

4. The image sensor of claim 3, wherein:
the active center portion has a first width in the first direction,
the first impurity region has a second width in the first direction,
the second impurity region has a third width in the first direction, and
the first width is greater than the second width and the third width.

5. The image sensor of claim 3, wherein:
the plurality of device separators each comprise:
a first separation sidewall and a second separation sidewall which are in contact with the active center portion and parallel to the second direction; and
a third separation sidewall and a fourth separation sidewall which are in contact with the active center portion and parallel to the first direction, and
when a straight line connecting a first point, at which the first active protrusion meets the active center portion and which is most adjacent to the fourth separation sidewall, and a second point, at which the second active protrusion meets the active center portion and which is most adjacent to the second separation sidewall, is a first straight line, and
a straight line connecting a third point, at which the first active protrusion meets the active center portion and which is most adjacent to the third separation sidewall, and a fourth point, at which the second active protrusion meets the active center portion and which is most adjacent to the third separation sidewall, is a second straight line,
an angle, formed by the first straight line and the fourth separation sidewall, and an angle formed by the second straight line and the third separation sidewall, are each an acute angle.

6. The image sensor of claim 5, wherein:
a third straight line connecting a center of the first active protrusion and a center of the second active protrusion is not parallel to either the first direction or the second direction, and
an angle formed by the third straight line and an axis in the first direction comprises an acute angle.

7. The image sensor of claim 6, wherein the third straight line is not parallel to either the first straight line or the second straight line.

8. The image sensor of claim 3, wherein at least one of a portion of the first active protrusion or a portion of the second active protrusion extends below the gate electrode.

9. The image sensor of claim 3, wherein
in the first active region among the first through fourth active regions,
a reset gate floating diffusion region is arranged adjacent to a protrusion closer to a transmission gate disposed between the first active protrusion and the second active protrusion, among the plurality of transmission gates.

10. The image sensor of claim 3, wherein
each of the first active protrusion and the second active protrusion comprises a right-angled triangle shape that has a side being in contact with the active center portion.

11. An image sensor comprising:
a substrate having a pixel region defined by a pixel separator;
a floating diffusion region arranged in the pixel region of the substrate;
a plurality of photoelectric transformation regions arranged around the floating diffusion region in the substrate;
a plurality of transmission gates respectively arranged adjacent to the plurality of photoelectric transformation regions; and
a semiconductor device comprising a plurality of device separators and a gate electrode, the plurality of device separators being respectively arranged adjacent to the plurality of transmission gates and defining an active region having an asymmetrical structure with reference to a first direction, and the gate electrode crossing the active region in the first direction and having a first gate sidewall and a second gate sidewall spaced apart from each other in a second direction orthogonal to the first direction, wherein:
the pixel separator comprises lateral extending portions extending in the first direction and the second direction toward a center portion of the pixel region, and
in a plan view,
the plurality of transmission gates are respectively connected to word lines,
the plurality of photoelectric transformation regions arranged in the pixel region are distinguished from each other by being arranged at two sides of the lateral extending portions in the first direction, and
the floating diffusion region is arranged in a space between the lateral extending portions arranged in the pixel region and facing each other in the second direction.

12. The image sensor of claim 11, wherein, in a plan view, at least a portion of the active region overlaps the floating diffusion region.

13. The image sensor of claim 11, wherein:
the substrate comprises a first surface and a second surface opposite to each other,
the pixel separator extends from the first surface to the second surface, and
a length of one of the lateral extending portions in a third direction, orthogonal to the first direction and the second direction, is less than a length of the pixel separator in the third direction.

14. The image sensor of claim 11, wherein:
active regions defined by the plurality of device separators construct first through fourth active regions, and
in a plan view,
at least one of the first through fourth active regions has a shape different from others, and
gate electrodes arranged adjacent to the first through fourth active regions have a same shape.

15. The image sensor of claim 14, comprising,
in the active region,
a first impurity region adjacent to the first gate sidewall; and
a second impurity region adjacent to the second gate sidewall, wherein:
the active region comprises
an active center portion overlapping the gate electrode;
a first active protrusion in which the first impurity region is arranged; and
a second active protrusion in which the second impurity region is arranged, and
a first width of the first active center portion in the first direction, a second width of the first impurity region in the first direction, and a third width of the second impurity region in the first direction are substantially same as each other.

16. The image sensor of claim 15, wherein:
a third straight line connecting a center of the first active protrusion and a center of the second active protrusion is not parallel to either the first direction or the second direction, and
the plurality of device separators each comprise
a fifth separation sidewall and a sixth separation sidewall which are in contact with the active center portion and parallel to the third straight line, and
an angle formed by the third straight line and an axis in the first direction is an acute angle.

17. The image sensor of claim 14, further comprising,
in the active region,
a first impurity region adjacent to the first gate sidewall; and
a second impurity region adjacent to the second gate sidewall, wherein:
the active region comprises:
an active center portion overlapping the gate electrode;
a first active protrusion in which the first impurity region is arranged; and
a second active protrusion in which the second impurity region is arranged, and
the first active protrusion and the second active protrusion are arranged in a symmetry to each other with reference to an axis in the second direction passing a center of the active center portion.

18. The image sensor of claim 17, wherein:
a first width of the active center portion in the first direction is greater than a second width of the first impurity region in the first direction and a third width of the second impurity region in the first direction, and
an angle formed by a fourth straight line, which connects a center of the first active protrusion and a center of the active center portion, and a fifth straight line, which connects a center of the second active protrusion and the center of the active center portion, comprises an obtuse angle.

19. An image sensor comprising:
a substrate having a pixel region defined by a pixel separator;
a floating diffusion region arranged in the pixel region of the substrate;
a plurality of photoelectric transformation regions arranged around the floating diffusion region in the substrate;
a plurality of transmission gates respectively arranged adjacent to the plurality of photoelectric transformation regions, wherein the plurality of transmission gates extend toward the floating diffusion region respectively in different directions;
a semiconductor device comprising a plurality of device separators and a gate electrode, the plurality of device separators being respectively arranged adjacent to the plurality of transmission gates and defining an active region having an asymmetry structure with reference to a first direction and a second direction orthogonal to the first direction, and the gate electrode crossing the active region in the first direction and having a first gate sidewall and a second gate sidewall spaced apart from each other in the second direction;
a first impurity region arranged in the active region and adjacent to the first gate sidewall; and
a second impurity region adjacent to the second gate sidewall, wherein:
the pixel separator comprises lateral extending portions extending in the first direction and the second direction toward a center portion of the pixel region, and
the active region constructs first through fourth active regions, and comprises:
an active center portion overlapping the gate electrode;
a first active protrusion in which the first impurity region is arranged; and
a second active protrusion in which the second impurity region is arranged, wherein:
the first active protrusion and the second active protrusion are arranged in a point symmetry with reference to a center of the active center portion, and
in a plan view,
the plurality of photoelectric transformation regions arranged in the pixel region are distinguished from each other by being arranged at two sides of the lateral extending portions in the first direction, and
the floating diffusion region is arranged in a space between the lateral extending portions arranged in the pixel region and facing each other in the second direction,
at least one of the first through fourth active regions has a shape different from others, and
the gate electrodes arranged adjacent to the first through fourth active regions has a same shape.

20. The image sensor of claim 19, wherein:
in the first active region among the first through fourth active regions,
a reset gate floating diffusion region is arranged adjacent to a protrusion closer to a transmission gate disposed between the first active protrusion and the second active protrusion, among the plurality of transmission gates, and
the transmission gate, disposed between the first active protrusion and the second active protrusion, and the reset gate floating diffusion region are spaced apart from each other.
